(19) United States
(12) Patent Application Publication
(10) Pub. No.: US 2022/0416718 A1
(43) Pub. Date: Dec. 29, 2022

(54) SOLAR PANEL TO WHICH HIGH-DAMPING STACKED REINFORCEMENT PART IS APPLIED

(71) Applicants: SOLETOP CO., LTD., Daejeon (KR); INDUSTRY-ACADEMIC COOPERATION FOUNDATION, CHOSUN UNIVERSITY, Gwangju (KR)

(72) Inventors: Hongrae KIM, Sejong-si (KR); Ho-Beom KIM, Daejeon (KR); Jung-Kyu LEE, Suwon-si (KR); Youngbo SAGONG, Daejeon (KR); Hyun-Ung OH, Gwangju (KR); Ji-Seong GO, Gwangju (KR)

(21) Appl. No.: 17/778,189

(22) PCT Filed: Aug. 12, 2020
(86) PCT No.: PCT/KR2020/010648

§ 371 Date: May 19, 2022

(30) Foreign Application Priority Data
Jan. 8, 2020 (KR) 10-2020-0002752

(51) Int. Cl. H02S 40/36; H02S 10/40; H02S 30/20; H02S 40/42; F16F 15/02; B32B 15/20; B32B 7/12; B32B 15/04

(52) U.S. Cl. CPC H02S 40/36; H02S 10/40; H02S 30/20; H02S 40/42; F16F 15/022; B32B 15/20; B32B 7/12; B32B 15/043; B64G 1/44

(57) ABSTRACT

The present invention relates to a solar panel to which a high-damping stacked reinforcement part is applied and, more specifically, to a solar panel to which a high-damping stacked reinforcement part is applied, comprising: a power generation unit for generating electrical energy; a coupling part to which the power generation unit is coupled, and which has a circuit formed therein; and a reinforcement part for reinforcing the rigidity of the coupling part and damping vibration to be transmitted, and thus the present invention can prevent the power generation unit from being damaged by vibration, or the solar panel from inducing wobbling of a satellite by failing to damp the vibration.

### TECHNICAL FIELD

The present invention relates to a solar panel to which a high-damping stacked reinforcement part is applied, and more particularly, to a solar panel to which a high-damping stacked reinforcement part capable of reinforcing rigidity of a panel generating electric power using a solar cell and improving damping ability is applied.

### BACKGROUND ART

In a very small size satellite, a solar cell generating electric power required to maintain a satellite system is attached to a satellite body. However, in a case where it is difficult to satisfy the required electric power only by attaching the solar cell to a surface of the satellite body, a solar panel 20 to which a plurality of solar cells 30 are attached is coupled onto a satellite body 10 as illustrated in FIG. 1. Such an unfoldable solar panel 20 is folded and accommodated when the satellite is launched and is unfolded using an unfolding device and the attached solar cells 30 generate electrical energy for maintaining the satellite system, after the satellite enters an orbit.

Conventionally, in order to minimize a weight of the satellite and facilitate an electrical connection between the solar cells 10, the plurality of solar cells 10 were directly attached to a printed circuit board (PCB) to form the solar panel 20, and the solar panel 20 was then coupled to the satellite body 10. However, since the printed circuit board has low rigidity and flexible characteristics, there was a problem that the solar panel is damaged due to dynamic displacement occurring under a vibration environment caused when the satellite is launched, and there was also a problem that low-frequency vibrations are caused due to excitation of by the solar panel due to acceleration occurring in a process of performing satellite attitude control. Therefore, thereafter, a method of reinforcing rigidity of a solar cell module by coupling a reinforcement member made of a metal material having higher rigidity than the PCB to the solar cell module has been proposed.

However, the reinforcement member made of the metal material has a higher density than the PCB, and thus, has a problem in increasing a total weight of the solar panel, such there is a disadvantage in applying the reinforcement member made of the metal material to a very small size satellite of which a volume and a weight are very limited. In addition, even though the solar panel is formed by coupling the reinforcement member made of the metal material to the PCB, a problem that the reinforcement member does not damp low-frequency vibrations still may not be solved. Therefore, the necessity to a new solar panel capable of reinforcing rigidity of the solar panel, but capable of minimizing an increase in weight of the satellite due to its low density, and effectively damping low-frequency vibrations by improving damping ability of the solar panel has increased.

### DISCLOSURE

### Technical Problem

The present invention has been made in an effort to solve the problems as described above, and an object of the present invention is to solve a problem that a solar cell is damaged due to vibrations in a satellite launch process and a low-frequency vibration problem occurring in a satellite attitude control process by improving rigidity and damping ability of a solar panel.

### Technical Solution

In one general aspect, a solar panel to which a high-damping stacked reinforcement part is applied includes: include a power generation part 100 generating electrical energy; a coupling part 200 to which the power generation part 100 is coupled and in which a circuit is formed; and a reinforcement part 300 reinforcing rigidity of the coupling part 200 and damping transferred vibrations.

In addition, the power generation part 100 may include a plurality of solar cells 110 electrically connected to each other.

Further, the coupling part 200 may be a printed circuit board (PCB) on which a circuit electrically connecting the respective solar cells 110 to each other is printed.

Further, the reinforcement part 300 may include a reinforcing layer 310 having a higher rigidity than the coupling part 100 and a damping layer 320 having elasticity or viscoelasticity.

Further, the reinforcing layer 310 may be formed of a printed circuit board and the damping layer 320 may be formed of a viscoelastic tape, and the reinforcement part 300 may be a laminate in which a plurality of reinforcing layers 310 are stacked with each of the damping layers 320 interposed therebetween.

Further, heat dissipation holes 330 through which heat generated from the power generation part 100 and the coupling part 200 is dissipated may be formed in the reinforcement part 300.

Further, the reinforcement part 300 may include an edge reinforcement part 300A formed along an edge of the coupling part 200 and having the heat dissipation holes 330 formed therein and a central reinforcement part 300B interconnecting one side and the other side of the edge reinforcement part 300A facing each other.

Further, the central reinforcement part 300B may include a plurality of central reinforcement unit bodies 300B-1 intersecting each other.

Further, a heat dissipation auxiliary layer having higher thermal conductivity than the coupling part 200 may be coupled to the coupling part 200 exposed through the heat dissipation holes 330.

Further, the heat dissipation auxiliary layer may be made of copper.

Further, an aircraft such as an unmanned aerial vehicle or a satellite that uses electrical energy generated by the solar panel to which a high-damping stacked reinforcement part is applied may be included.

### Advantageous Effects

In the solar panel to which a high-damping stacked reinforcement part is applied according to the present invention, the reinforcement part not only reinforces rigidity of the coupling part, but also has damping ability to damp transferred vibrations, thereby making it possible to prevent the power generation part from being damaged by external force or vibration and to prevent a problem that a quality of a captured image of a satellite is deteriorated due to low-frequency vibrations generated in a satellite attitude control process.

In detail, the reinforcement part having rigidity of a predetermined level or more and damping ability is formed by stacking printed circuit boards having rigidity of a predetermined level or more and having flexible characteristics and tapes having viscoelastic properties, and is then attached to the coupling part to which the power generation part generating electrical energy like the solar cells is attached, thereby reinforcing insufficient rigidity and damping ability of the coupling part.

In addition, the heat dissipation holes are formed in the reinforcement part, and thus, the heat generated from the power generation part and the coupling part may be more efficiently dissipated.

Further, the heat dissipation auxiliary layer made of copper having high thermal conductivity is formed on the coupling part exposed to the outside through the heat dissipation holes, and thus, heat dissipation performance may be further improved.

Further, the solar panel to which a high-damping stacked reinforcement part is applied is light in weight and has sufficient rigidity and damping performance, and may thus be applied to various aircrafts.

### DESCRIPTION OF DRAWINGS

FIG. 1 is a perspective view illustrating that a solar panel according to the related art is coupled to a wing of a satellite.

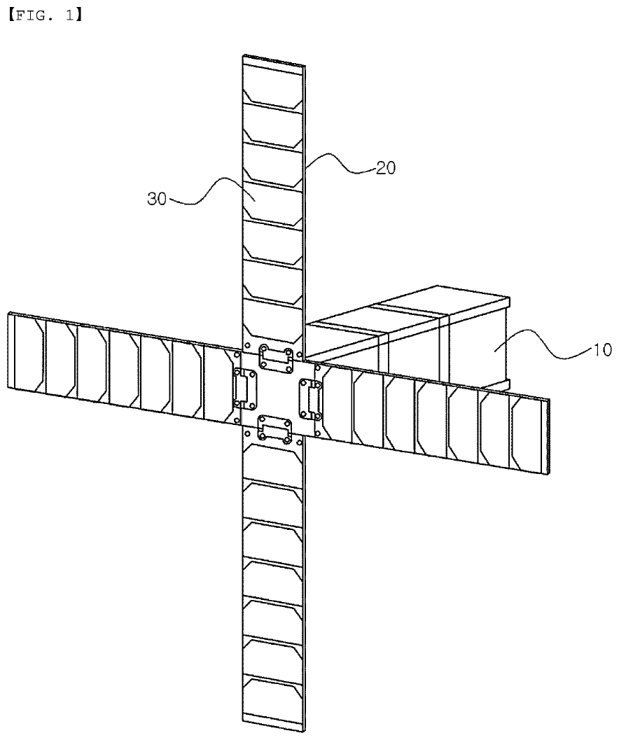

FIG. 2 is a perspective view and a partially enlarged view illustrating a solar panel to which a high-damping stacked reinforcement part is applied according to a first embodiment of the present invention.

FIG. 3 is an exploded perspective view illustrating the solar panel to which a high-damping stacked reinforcement part is applied according to a first embodiment of the present invention.

FIG. 4 is an exploded perspective view illustrating a solar panel to which a high-damping stacked reinforcement part is applied according to a second embodiment of the present invention.

FIG. 5 is a side view illustrating the solar panel to which a high-damping stacked reinforcement part is applied according to a second embodiment of the present invention.

FIG. 6 is a perspective view illustrating that a heat dissipation auxiliary layer is coupled to the solar panel to which a high-damping stacked reinforcement part is applied according to a second embodiment of the present invention.

FIG. 7 is graphs illustrating free damping vibration experiment results of the solar panel to which a high-damping stacked reinforcement part is applied according to the present invention and the solar panel according to the related art.

FIG. 8 is graphs illustrating low level sine sweep (LLSS) vibration experiment results of the solar panel to which a high-damping stacked reinforcement part is applied according to the present invention and the solar panel according to the related art.

FIG. 9 is graphs illustrating random vibration experiment results of the solar panel to which a high-damping stacked reinforcement part is applied according to the present invention and the solar panel according to the related art

FIG. 10 is table showing the frequency and damping ratio of the power generation device according to applied or not applied of the reinforcement part and the type of the reinforcing part.

### BEST MODE

Various advantages and features of embodiments of the present invention and methods accomplishing them will become apparent from the following detailed description of exemplary embodiments with reference to the accompanying drawings. However, the present invention is not limited to embodiments to be described below, but may be implemented in various different forms, these embodiments will be provided only in order to make the present invention complete and allow those skilled in the art to completely recognize the scope of the present invention, and the present invention will be defined by the scope of the claims. Throughout the specification, the same reference numerals denote the same components.

[symbol]

In describing exemplary embodiments of the present invention, when it is decided that a detailed description for well-known functions and configurations may unnecessarily obscure the gist of the present invention, the detailed description will be omitted. In addition, the following terms are terms defined in consideration of the functions in exemplary embodiments of the present invention, and may be construed in different ways by the intention of users and operators, customs, or the like. Therefore, these terms should be defined on the basis of contents throughout the present specification.

[symbol]

Hereinafter, a solar panel 1000 to which a high-damping stacked reinforcement part is applied according to the present invention will be described with reference to the accompanying drawings.

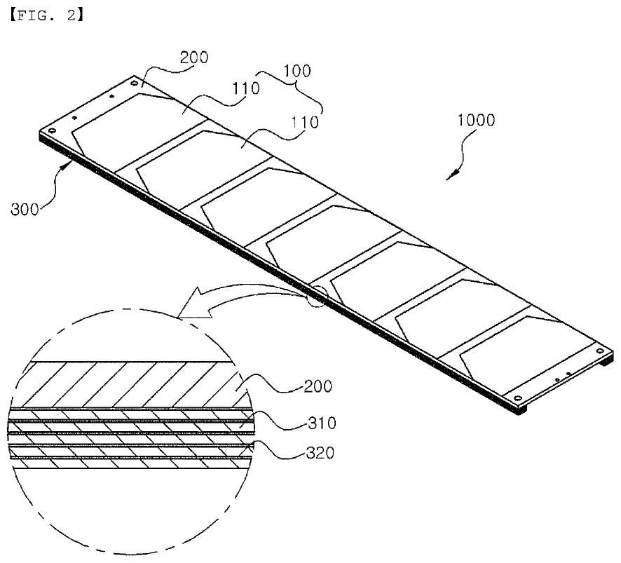

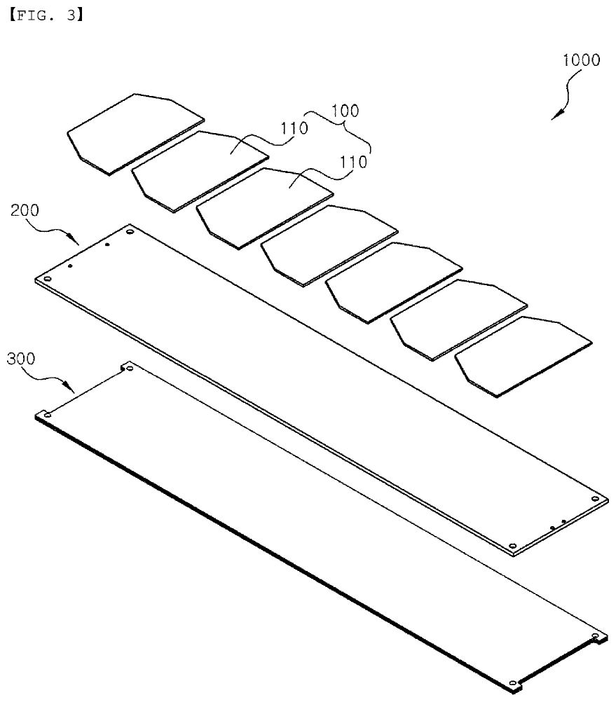

A perspective view and a partially enlarged view illustrating a solar panel to which a high-damping stacked reinforcement part is applied according to a first embodiment of the present invention are illustrated in FIG. 2, and an exploded perspective view illustrating the solar panel to which a high-damping stacked reinforcement part is applied according to a first embodiment of the present invention is illustrated in FIG. 3.

Referring to FIGS. 2 and 3, the solar panel 1000 to which a high-damping stacked reinforcement part is applied according to the present invention may include a power generation part 100 generating electrical energy, a coupling part 200 to which the power generation part 100 is coupled and in which a circuit is formed, and a reinforcement part 300 reinforcing rigidity of the coupling part 200 and damping transferred vibrations.

In detail, since a satellite should generate electric power for maintaining a satellite system by itself, a solar panel capable of generating electric power is mounted on the satellite in the form of a wing. In general, such a solar panel may be a power generation device using sunlight that may be easily supplied from space. The solar panel generates the electric power using a potential difference appearing when the sunlight is applied to electrodes, a plurality of solar cells are attached to the solar panel in order to generate sufficient electric power for maintaining the satellite system, and these solar cells are electrically connected to each other to form one solar module. In this case, the solar cells may be directly mounted on the solar panel, but when the solar cells are connected to each other by electric wires after the solar cells are mounted on a wing part of the satellite, an additional space in which the electric wires are stored is required in the satellite. Therefore, generally, the plurality of solar cells are electrically connected to each other by mounting the plurality of solar cells on a printed circuit board and then printing a circuit on the printed circuit board.

However, since the printed circuit board has lower structural rigidity than a metal such as aluminum, in a case where dynamic displacement occurs under a vibration environment caused at the time of launching the satellite, a problem that the solar cells mounted in the printed circuit board are damaged may occur, and there is a problem that ability to damp low-frequency vibrations generated in a satellite attitude control process is insufficient. Accordingly, conventionally, insufficient rigidity of the printed circuit board (PCB) was reinforced by attaching a rigid member made of a metal material to the printed circuit board. However, since the rigid member made of the metal material has a high density, there was a problem that a weight is excessively increased compared to a case of using only the printed circuit board, and a low-frequency vibration problem was not solved due to an insufficiency of damping ability. Therefore, in the present invention, a risk of damage to the solar cells due to the dynamic displacement in an environment in which the satellite is launched may be reduced and the low-frequency vibrations occurring at the time of performing satellite attitude control on an orbit may be effectively damped, by coupling the reinforcement part 300 capable of improving damping ability simultaneously with reinforcing rigidity of the coupling part 200 onto the coupling part 200 in which the power generation part 100 generating the electrical energy is formed.

In this case, the power generation part 100 may include various devices capable of generating the electrical energy, and the coupling part 200 may be a plate to which each component constituting the power generation part 100 is coupled. As an example, as illustrated in FIG. 3, the power generation part 100 may be a solar cell 110 receiving sunlight to generate electricity, and the coupling part 200 may be a printed circuit board (PCB) to which the solar cell 110 is coupled and in which a circuit electrically connecting a plurality of coupled solar cells 110 to each other is printed.

[symbol]

In addition, the reinforcement part 300 may be a member made of various materials or a structure having a specific structure, which may have rigidity of a predetermined level or more to limit damage to the power generation part 100 due to deformation of the coupling part 200 in a vibration environment in which the satellite is launched and may have a damping ability to absorb the vibrations transferred to the power generation part 100. As an example, the reinforcement part 300 may be a laminate in which reinforcing layers 310 formed of a printed circuit board (PCB) and damping layers 320 formed of a viscoelastic double-sided tape having viscoelastic properties may be alternately stacked, as illustrated in a partially enlarged view of FIG. 2.

In detail, the reinforcement part 300 may have sufficient rigidity by stacking a plurality of printed circuit boards (PCBs), but may effectively damp a vibration response in the form of bending behavior appearing while the vibrations are transferred, by friction between the viscoelastic double-sided tapes and the printed circuit boards by connecting the printed circuit boards (PCBs) to each other with the tapes having the viscoelastic properties. In this case, the viscoelastic double-sided tape may be made of various materials having a viscoelastic material and capable of adhering the reinforcement part 300 to be stacked. As an example, the viscoelastic double-sided tape may be a 3M 966 double-sided tape that is actually used in space.

[symbol]

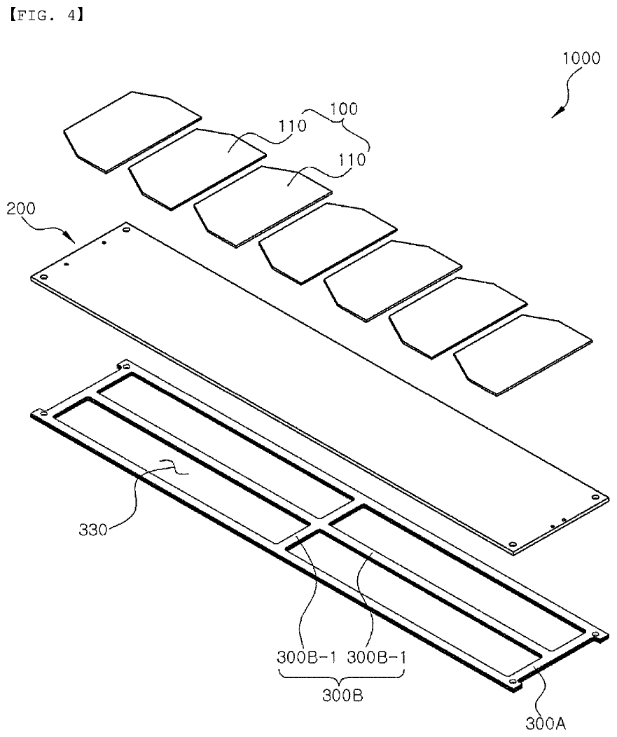

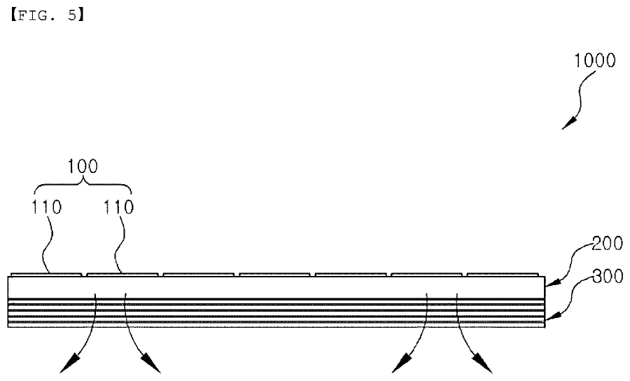

An exploded perspective view illustrating a solar panel 1000 to which a high-damping stacked reinforcement part is applied according to a second embodiment of the present invention is illustrated in FIG. 4, and a side view illustrating the solar panel 1000 to which a high-damping stacked reinforcement part is applied according to a second embodiment of the present invention is illustrated in FIG. 5.

Referring to FIG. 4, in the solar panel 1000 to which a high damping stacked reinforcement part is applied according to a second embodiment of the present invention, heat dissipation holes 330 through which heat generated by the power generation part 100 and the coupling part 200 is dissipated may be formed in the reinforcement part 300.

In detail, the coupling part 200 in which the plurality of solar cells 110 constituting the power generation part 100 and the circuit electrically connecting the plurality of solar cells 110 to each other are formed generates a predetermined amount or more of heat. Such heat may not only reduce power generation performance of the power generation part 100 but also act as a factor that reduces durability of a device. Therefore, in the present invention, the heat dissipation holes 330 are drilled in a direction facing the coupling part 200 in the reinforcement part 300, as illustrated in FIG. 4, such that the heat generated by the power generation part 100 and the coupling part 200 may be dissipated through the heat dissipation holes 330, as illustrated in FIG. 5.

[symbol]

In addition, as illustrated in FIG. 4, the reinforcement part 300 may include an edge reinforcement part 300A formed along an edge of the coupling part 200 and having the heat dissipation holes 330 formed therein and a central reinforcement part 300B interconnecting one side and the other side of the edge reinforcement part 300A facing each other, wherein the central reinforcement part 300B may include a plurality of central reinforcement unit bodies 300B-1 interconnecting inner peripheral surfaces of the edge reinforcement part 300A facing each other and intersecting each other.

In detail, since a load is limited to a predetermined level or less in a very small size satellite, in the present invention, the heat dissipation holes 330 are formed in a central region of the reinforcement part 300 to decrease a weight of the device and facilitate dissipation of the heat generated by the coupling part 200, but inner side surfaces of the edge reinforcement part 300A facing each other are connected to each other by the central reinforcement unit bodies 300B-1 in order to prevent rigidity of the reinforcement part 300 from being decreased at the time of forming the heat dissipation holes 330 in the central region of the reinforcement part 300.

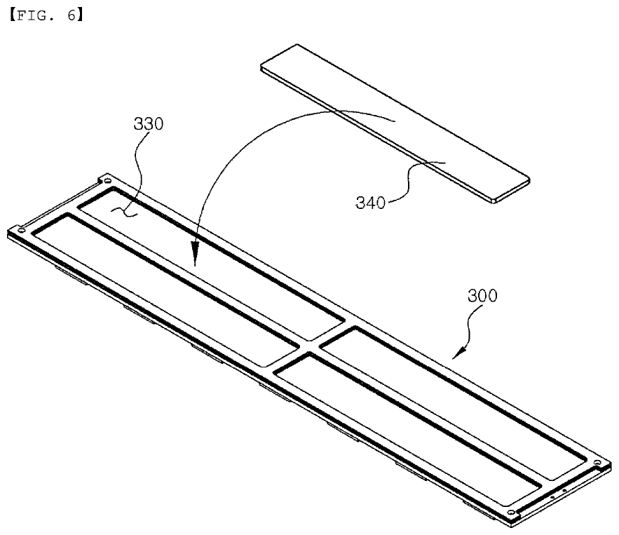

In addition, in the solar panel 1000 to which a high-damping stacked reinforcement part is applied according to the present invention, as illustrated in FIG. 6, a heat dissipation auxiliary layer 340 having higher thermal conductivity than the coupling part 200 may be coupled to the coupling part 200 exposed through the heat dissipation holes 330 in order to more effectively cool the power generation part 100 and the coupling part 200, and a material of the coupling part 200 may be copper.

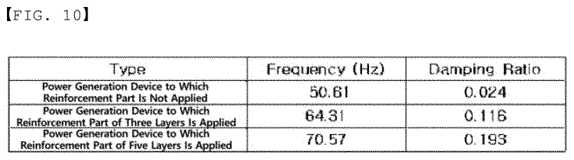

In addition, rigidity and damping ability of the solar panel may be increased according to the numbers of stacked reinforcing layers 310 and damping layers 320 according to a second embodiment, the numbers of reinforcing layers 310 and damping layers 320 may be adjusted and used as necessary, and this fact may be confirmed through a table of FIG. 10.

[symbol]

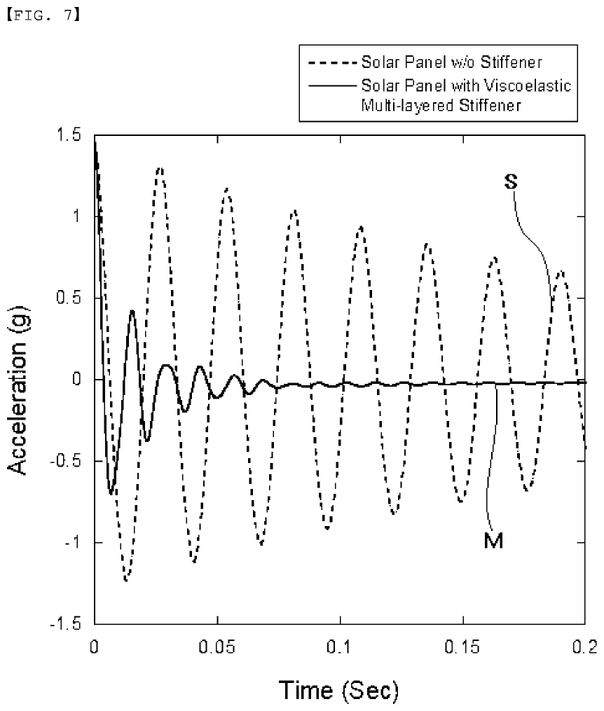

In addition, the solar panel to which the high-damping stacked reinforcement part is applied according to in which such a stacked reinforcement part 300 is formed have very excellent damping ability as compared with a conventional solar panel manufactured using a PCB without the reinforcement part, and such excellent performance will be described below with reference to experimental data illustrated in FIGS. 7 to 9. In addition, in experimental data, the present invention in which the stacked reinforcement part 300 is formed is indicated as Solar Panel with Viscoelastic Multi-layered Stiffener, and the conventional solar panel manufactured using the PCB and without the reinforcement part is indicated as Solar Panel w/o Stiffener.

In FIGS. 7 to 9, experiment data compared between the solar panel 1000 to which a high-damping stacked reinforcement part is applied according to a second embodiment of the present invention described above and the conventionally used solar panel manufactured using the PCB without the reinforcement part through a free vibration damping experiment, a low level sine sweep (LLSS) vibration experiment, and a random vibration experiment are illustrated.

Referring to the experimental data illustrating a free damping vibration experiment result of FIG. 7, it can be seen that a vibration damping ratio of the solar panel 1000 to which a high-damping stacked reinforcement part is applied, which is calculated from a logarithmic decrement over time and appears through a graph M, is 0.193, which is about 8 times higher than a vibration damping ratio (0.024) of the conventional solar panel manufactured using the PCB without the reinforcement part, which appears through a graph S, and this is a numerical value with a significant difference in damping ability that may not appear when a metal material of a rigid member is simply changed. Such vibration damping ability is an effect appearing due to friction between the reinforcing layers and the damping layers stacked and adhered and connected to each other as described above against the vibrations, and the same effect may not be obtained even though the reinforcement part formed of the metal material is simply coupled to the conventional solar panel.

[symbol]

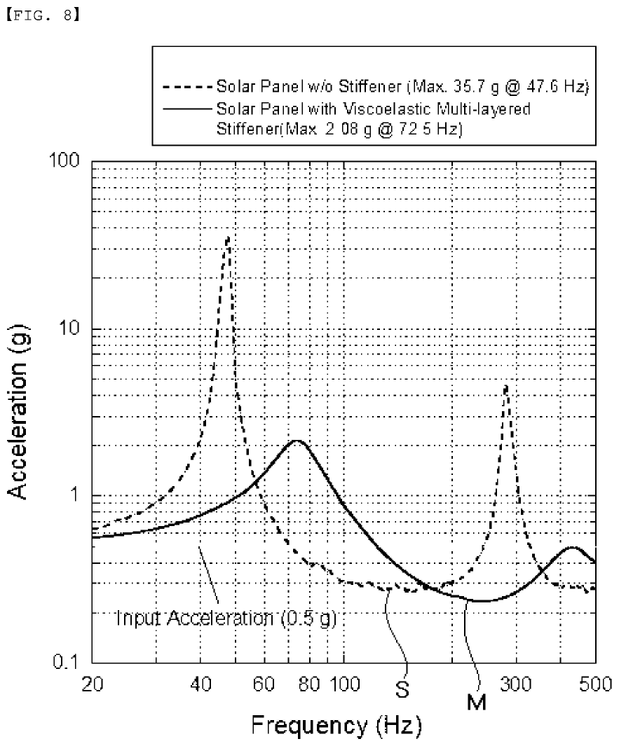

Referring to experimental results appearing at the time of performing the LLSS vibration experiment at an amplitude of 0.5 g and in a frequency range of 20 to 500 HZ of FIG. 8, it may be confirmed that a vibration amplification ratio of the solar panel 1000 to which a high-damping stacked reinforcement part is applied, which appears through a graph M, is about 4.2, which is about 17.2 times lower than a vibration amplification ratio of the conventional solar panel manufactured using the PCB without the reinforcement part, which appears through a graph S.

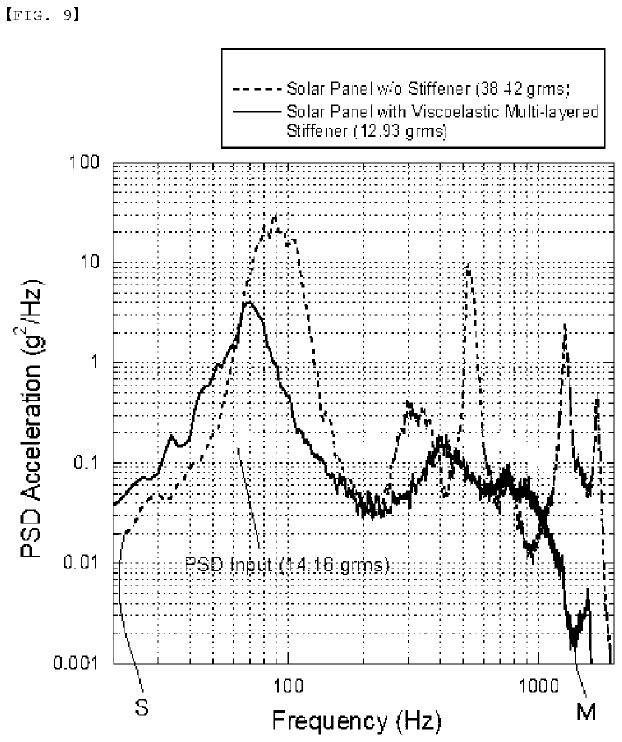

Referring to experimental results appearing at the time of performing the random vibration experiment at an actual launch environment level of FIG. 9, it may be confirmed that a root mean square (RMS) acceleration of the solar panel 1000 to which a high-damping stacked reinforcement part is applied, which appears through a graph M, is 12.93 grms, which is decreased about 3 times as compared with the conventional solar panel manufactured using the PCB without the reinforcement part, which appears through a graph S.

As a result, it may be confirmed that the solar panel to which a high-damping stacked reinforcement part is applied according to the present invention has significant vibration damping ability as compared with the conventional solar panel manufactured using the PCB without the reinforcement part, and has a vibration amplification rate and an acceleration deviation smaller than those of the conventional solar panel manufactured using the PCB without the reinforcement part to have significant damping ability.

In FIG. 10, when the reinforcement part is applied to the power generation device, the frequency and damping ratio increase, and as the reinforcement part is added, the frequency and attenuation ratio increase.

[symbol]

In addition, it is recommended that the solar panel to which a high-damping stacked reinforcement part is applied as described above is used for a satellite, but the solar panel to which a high-damping stacked reinforcement part is applied may also be coupled to an aircraft such as an airplane to supply electrical energy to the aircraft. In the present invention, the coupling part 200 may be a member having various plate forms to which the power generation part 100 may be coupled, in addition to the printed circuit board. As an example, the coupling part 200 may be a plate made of aluminum or graphite.

[symbol]

In addition, although not illustrated in the drawings, in the present invention, the reinforcement part 300 may have a structure in which a surface area of the damping layer 320 positioned between the reinforcing layers 310 is increased by forming patterns having a ruggedness shape on a surface of the reinforcing layer 310 or forming patterns having a ruggedness shape on one side surface of the reinforcement part 300 in a stacked direction and forming grooves corresponding to the patterns having the ruggedness shape in the other side surface of the reinforcement part 300. In order to maximize the surface area of the damping layer 320, grooves corresponding to the patterns having the ruggedness shape, formed on the surface of the reinforcement part 300 may also be formed in a lower surface of the coupling part 200 to which the reinforcement part 300 is coupled.

[symbol]

In addition, although not illustrated in the drawings, a copper layer for increasing damping characteristics may be formed on one or more of an upper surface, a lower surface, and the inside of the reinforcing layer 310. The reinforcement part may have higher damping characteristics at the time of forming the copper layer than at the time of forming the reinforcing layer 310 using a general plastic or metal-based stiffener.

[symbol]

The present invention is not limited to the exemplary embodiments described above, but may be variously applied. In addition, the present invention may be variously modified by those skilled in the art to which the present invention pertains without departing from the gist of the present invention claimed in the claims.

1. A solar panel to which a high-damping stacked reinforcement part is applied, comprising:
include a power generation part 100 generating electrical energy;
a coupling part 200 to which the power generation part 100 is coupled and in which a circuit is formed; and
a reinforcement part 300 reinforcing rigidity of the coupling part 200 and damping transferred vibrations.

2. The solar panel to which a high-damping stacked reinforcement part is applied of claim 1, wherein the power generation part 100 includes a plurality of solar cells 110 electrically connected to each other.

3. The solar panel to which a high-damping stacked reinforcement part is applied of claim 2, wherein the coupling part 200 is a printed circuit board (PCB) on which a circuit electrically connecting the respective solar cells 110 to each other is printed.

4. The solar panel to which a high-damping stacked reinforcement part is applied of claim 3, wherein the reinforcement part 300 includes a reinforcing layer 310 having a higher rigidity than the coupling part 00 and a damping layer 320 having elasticity or viscoelasticity.

5. The solar panel to which a high-damping stacked reinforcement part is applied of claim 4, wherein the reinforcing layer 310 is formed of a printed circuit board, and the damping layer 320 is formed of a viscoelastic tape, and
the reinforcement part 300 is a laminate in which a plurality of reinforcing layers 310 are stacked with each of the damping layers 320 interposed therebetween.

6. The solar panel to which a high-damping stacked reinforcement part is applied of claim 3, wherein heat dissipation holes 330 through which heat generated from the power generation part 100 and the coupling part 200 is dissipated are formed in the reinforcement part 300.

7. The solar panel to which a high-damping stacked reinforcement part is applied of claim 6, wherein the reinforcement part 300 includes an edge reinforcement part 300A formed along an edge of the coupling part 200 and having the heat dissipation holes 330 formed therein and a central reinforcement part 300B interconnecting one side and the other side of the edge reinforcement part 300A facing each other.

8. The solar panel to which a high-damping stacked reinforcement part is applied of claim 7, wherein the central reinforcement part 300B includes a plurality of central reinforcement unit bodies 300B-1 intersecting each other.

9. The solar panel to which a high-damping stacked reinforcement part is applied of claim 6, wherein a heat dissipation auxiliary layer having higher thermal conductivity than the coupling part 200 is coupled to the coupling part 200 exposed through the heat dissipation holes 330.
